(19) United States
(12) Patent Application Publication
(10) Pub. No.: US 2026/0122938 A1
(43) Pub. Date: Apr. 30, 2026

(54) SEMICONDUCTOR DEVICE, AND METHOD OF MANUFACTURING SEMICONDUCTOR DEVICE

(71) Applicant: Mitsubishi Electric Corporation, Tokyo (JP)

(72) Inventor: Tetsuo TAKAHASHI, Tokyo (JP)

(73) Assignee: Mitsubishi Electric Corporation, Tokyo (JP)

(21) Appl. No.: 19/304,096

(22) Filed: Aug. 19, 2025

(30) Foreign Application Priority Data
Oct. 30, 2024 (JP) 2024-190591

(51) Int. Cl. H10D 12/00; H10D 12/01; H10D 30/01; H10D 30/66; H10D 62/10; H10D 62/60

(52) U.S. Cl. CPC H10D 12/415; H10D 12/038; H10D 12/481; H10D 30/0297; H10D 30/665; H10D 30/668; H10D 62/102; H10D 62/126; H10D 62/60

(57) ABSTRACT

A semiconductor device includes a semiconductor layer of a first conductivity type provided in an active region and a termination region and a channel stop portion provided inside an outer end portion of the termination region, in which the channel stop portion includes a first channel stop groove portion formed to reach the inside from an upper surface of the semiconductor layer, a first impurity portion of the first conductivity type formed in a surface layer of the semiconductor layer outside the first channel stop groove portion, and a second impurity portion of the first conductivity type formed in a bottom portion of the first channel stop groove portion, and impurity concentrations of the first and second impurity portions are higher than that of the semiconductor layer.

### BACKGROUND

### Technical Field

The technique disclosed in the present description relates to a semiconductor device.

### Description of the Background Art

As a method of stabilizing operation of a termination region of a semiconductor device, a structure in which a structure portion called a channel stop is provided at an outermost peripheral portion of the termination region is disclosed (see, for example, Japanese Patent Application Laid-Open No. 2013-138137).

In a termination structure in a semiconductor device of a conventional technique, there is room for improvement in an effect that a channel stop suppresses a depletion layer, moisture resistance, or the like.

### SUMMARY

The technique disclosed in the present description is a technique for improving reliability of a semiconductor device.

A semiconductor device according to a first aspect of the technique disclosed in the present description is a semiconductor device including an active region in which an element structure is formed, and a termination region surrounding the active region in plan view, the semiconductor device including a semiconductor layer of a first conductivity type provided in the active region and the termination region, and a channel stop portion provided inside an outer end portion of the termination region, in which the channel stop portion includes a first channel stop groove portion formed to reach an inside from an upper surface of the semiconductor layer, a first impurity portion of the first conductivity type formed on a surface layer of the semiconductor layer outside the first channel stop groove portion, and a second impurity portion of the first conductivity type formed in a bottom portion of the first channel stop groove portion, and impurity concentration of the first impurity portion and impurity concentration of the second impurity portion are higher than impurity concentration of the semiconductor layer.

According to at least the first aspect of the technique disclosed in the present description, since it is possible to suppress extension of a depletion layer from the channel stop portion, withstand voltage of the semiconductor device is stabilized and reliability is improved.

Further, an object, a feature, an aspect, and an advantage relating to the technique disclosed in the present description will be further clarified by detailed description below and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating an example of a configuration of a semiconductor device relating to a preferred embodiment;

FIG. 2 is a plan view illustrating an example of arrangement in a wafer surface of an element region in a manufacturing process;

FIG. 3 is a plan view of an active region corresponding to a region 105 in FIG. 1;

FIG. 4 is a cross-sectional view corresponding to a cross section taken along line A-A′ in FIG. 3;

FIG. 5 is a plan view of a region corresponding to a region 106 in FIG. 1;

FIG. 6 is a cross-sectional view corresponding to a cross section taken along line B-B′ in FIG. 5;

FIGS. 7 to 24 are cross-sectional views illustrating an example of a method of manufacturing the semiconductor device relating to the preferred embodiment;

FIG. 25 is a cross-sectional view illustrating an example of a depletion layer in a cross section taken along line A-A′ of FIG. 3;

FIG. 26 is a cross-sectional view illustrating an example of a depletion layer in a cross section taken along line B-B′ of FIG. 5;

FIGS. 27, 29, 31, 33, 35, 37, and 41 are plan views of a region corresponding to the region 106 in FIG. 1 relating to the preferred embodiment;

FIG. 28 is a cross-sectional view corresponding to a cross section taken along line B-B′ in FIG. 27;

FIG. 30 is a cross-sectional view corresponding to a cross section taken along line B-B′ in FIG. 29;

FIG. 32 is a cross-sectional view corresponding to a cross section taken along line B-B′ in FIG. 31;

FIG. 34 is a cross-sectional view corresponding to a cross section taken along line B-B′ in FIG. 33;

FIG. 36 is a cross-sectional view corresponding to a cross section taken along line B-B′ in FIG. 35;

FIG. 38 is a cross-sectional view corresponding to a cross section taken along line B-B′ in FIG. 37;

FIG. 39 is a plan view of an active region corresponding to the region 105 in FIG. 1 relating to the preferred embodiment;

FIG. 40 is a cross-sectional view corresponding to a cross section taken along line A-A′ in FIG. 39; and

FIG. 42 is a cross-sectional view corresponding to a cross section taken along line B-B′ in FIG. 41.

### DESCRIPTION OF THE PREFERRED EMBODIMENTS

Hereinafter, a preferred embodiment will be described with reference to the attached drawings. In a preferred embodiment below, a detailed feature and the like are also shown for explanation of a technique, but they are merely examples, and not all of them are necessarily essential features for enabling the preferred embodiment to be carried out.

Note that the drawings are shown schematically, and for convenience of explanation, a configuration is omitted or a configuration is simplified or the like on the drawings as appropriate. Further, an interrelationship between sizes and positions of configurations and the like shown in different drawings is not always accurately described and may be changed as appropriate. Further, hatching may be applied to a drawing such as a plan view that is not a cross-sectional view in order to facilitate understanding of content of a preferred embodiment.

Further, in description shown below, similar constituent elements are illustrated with the same reference numerals. This similarly applies to their names and functions. Therefore, there is a case where detailed description of them is omitted to avoid duplication.

Further, in description described in the description of the present application, in a case where description of “comprising”, “including”, or “having” a certain constituent element or the like is shown, such an expression is not an exclusive expression for excluding the presence of other constituent elements unless otherwise specified.

In description described in the description of the present application, even if ordinal numbers such as “first” or “second” are used, these terms are used for convenience to facilitate understanding of content of the preferred embodiment, and the content of the preferred embodiment is not limited to order or the like that may be caused by these ordinal numbers.

Further, in the description described in the present description, a case where “A or B” is described includes a case where only one of A and B is indicated and a case where both A and B are indicated as long as there is no contradiction.

Further, in description described in this description, even in a case where terms meaning specific positions or directions such as “upper”, “lower”, “left”, “right”, “side”, “bottom”, “front”, or “back” are used, these terms are used for convenience to facilitate understanding of content of a preferred embodiment, and are not related to positions or directions when the preferred embodiment is actually implemented.

Further, in description described in the present description, in a case where “upper surface of . . . ”, “lower surface of . . . “, or the like is described, it is intended to include a state in which another constituent element is formed on an upper surface or a lower surface of a target constituent element in addition to the upper surface itself or the lower surface itself of the target constituent element. That is, for example, in a case where “B provided on an upper surface of A” is described, interposition of another constituent element “C” between A and B is not excluded.

A power semiconductor device generally called a power device is used for a switching element or the like for controlling power supply to a motor load or the like. Although a power device is required to have several performances, one of the most basic requirements is withstand voltage retention.

Power devices are often used in harsh environments such as high altitude, high temperature, or high humidity, and withstand voltage retention is important. Furthermore, it is also required to realize required performance at lowest possible cost.

Examples of a semiconductor element used in a power semiconductor device include an insulated gate semiconductor device such as a metal-oxide-semiconductor field-effect transistor (in other words, MOSFET), or an insulated gate bipolar transistor (in other words, IGBT), and in recent years, a MOSFET or an IGBT using a wide band gap semiconductor such as silicon carbide (SiC) has been proposed.

A power semiconductor device has a structure in which a termination region is provided around an active region in which main current flows in order for withstand voltage retention. A plurality of structures of this termination region have been proposed, and structures such as field limiting ring (FLR) and variation of lateral doping (VLD) are known. A termination region having these structures is desirably formed in a region as small as possible from the viewpoint of reducing manufacturing cost, but stability or reliability of withstand voltage may be insufficient.

As a method for stabilizing operation of a termination region, a structure in which a structure portion called a channel stop is provided at an outermost peripheral portion of the termination region is disclosed.

In Japanese Patent Application Laid-Open No. 2013-138137, a groove is formed inside a substrate, and a high concentration impurity region having the same conductivity type as that of a drift layer is provided as a channel stop on a bottom portion and a side surface portion of the groove. When a channel stop is formed, there is a concern that manufacturing cost increases for stably forming a high concentration region.

Japanese Patent Application Laid-Open No. 2005-136116 discloses an example in which a groove of a channel stop is formed by substrate etching in a contact forming step in order to reduce manufacturing cost. However, there is room for improvement in a point that a high concentration region is scraped at the time of etching, moisture resistance, or the like.

Japanese Patent Application Laid-Open No. 2012-004466 discloses an example in which a plurality of high concentration impurity regions having the same conductivity type as that of a drift layer is provided in a channel stop to stabilize withstand voltage. However, there is room for improvement in a point that a high concentration region is scraped at the time of etching, high manufacturing cost, or the like.

Japanese Patent Application Laid-Open No. 2013-030501 discloses a technique of forming a channel stop in a dug portion while suppressing manufacturing cost. However, since no channel stop is formed on a surface of a substrate, there is room for improvement in stability of withstand voltage.

Further, in the above example, there is room for improvement in measurements taken during activation annealing for activating an introduced impurity in a semiconductor device using SiC as a semiconductor material. Since temperature becomes very high during activation annealing of SiC, a pattern formed of an insulating film or polysilicon may disappear during the activation annealing. For this reason, it is necessary to remove these patterns before activation annealing.

### First Preferred Embodiment

Hereinafter, a semiconductor device and a method of manufacturing a semiconductor device according to the present preferred embodiment will be described.

### <Regarding Configuration of Semiconductor Device>

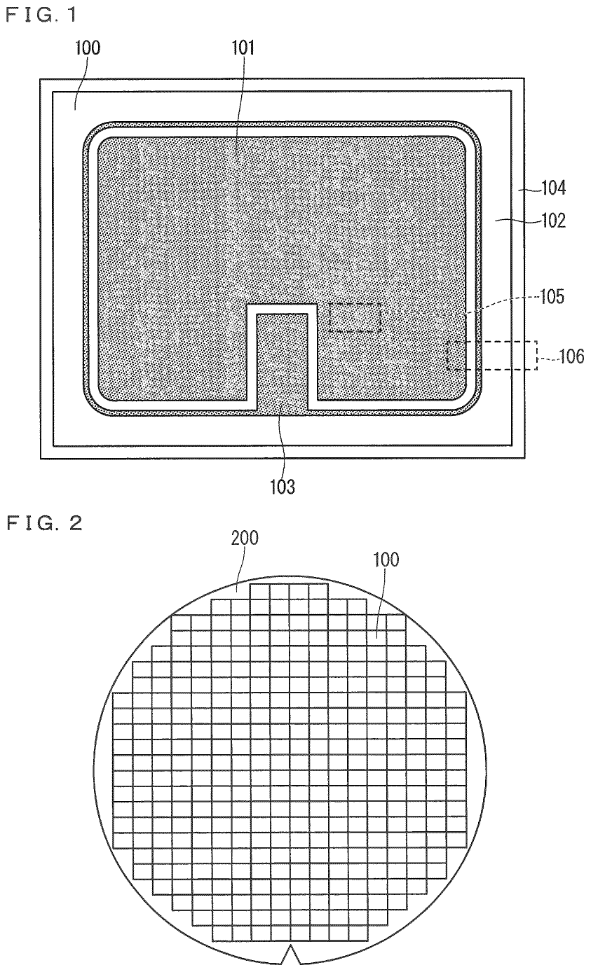

FIG. 1 is a plan view illustrating an example of a configuration of a semiconductor device relating to the present preferred embodiment. As illustrated in FIG. 1, an element region 100 of the semiconductor device includes an active region 101 and a termination region 102 surrounding the active region 101 in plan view.

In the termination region 102, a gate pad region 103 (control electrode) and a gate wiring arranged so as to surround the active region 101 are provided. A dicing line region 104 for cutting out a chip is located on an outer peripheral portion of the termination region 102. The dicing line region 104 is formed to surround the termination region 102 in plan view.

In FIG. 1, a region 105 is a region obtained by cutting out a part of the active region 101, and a region 106 is a region extending over an end portion of the active region 101, the termination region 102, and the dicing line region 104.

FIG. 2 is a plan view illustrating an example of arrangement in a wafer surface of an element region in a manufacturing process. As illustrated in the example of FIG. 2, the element region 100 corresponds to a portion within a wafer surface 200.

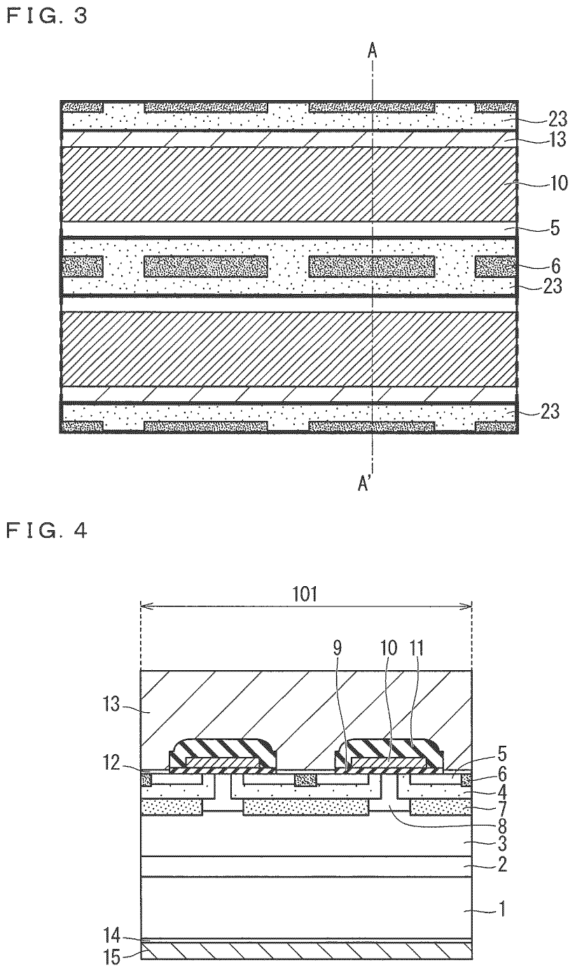

FIG. 3 is a plan view of the active region 101 corresponding to the region 105 in FIG. 1. FIG. 4 is a cross-sectional view corresponding to a cross section taken along line A-A′ in FIG. 3.

As illustrated in FIGS. 3 and 4, the semiconductor device includes, in the active region 101, an n+ substrate 1, an n+ buffer layer 2 provided on an upper surface of the n+ substrate 1, an n-drift layer 3 provided on an upper surface of the n+ buffer layer 2, a plurality of p channel doped layers 4 formed on a surface layer of the n-drift layer 3, an n+ source layer 5 formed on a surface layer of each of the p channel doped layers 4, a p+ contact layer 6 formed on a surface layer of each of the p channel doped layers 4, a p well layer 7 formed below each of the p channel doped layers 4, and an nJFET doped layer 8 formed between a plurality of the p channel doped layers 4, a gate electrode layer 10 (polysilicon) adjacent to the p channel doped layer 4 sandwiched between the n+ source layer 5 and the nJFET doped layer 8 with a gate insulating film 9 interposed between them, an interlayer insulating film 11 formed to cover the gate electrode layer 10, a silicide layer 12 formed to cover the n+ source layer 5 exposed from the gate insulating film 9 and the p+ contact layer 6 exposed from the gate insulating film 9, a source electrode 13 formed to cover the interlayer insulating film 11 and the silicide layer 12, a silicide layer 14 provided on a lower surface of the n+ substrate 1, and a drain electrode 15 provided on a lower surface of the silicide layer 14. In FIG. 3, a source contact region 23 is illustrated.

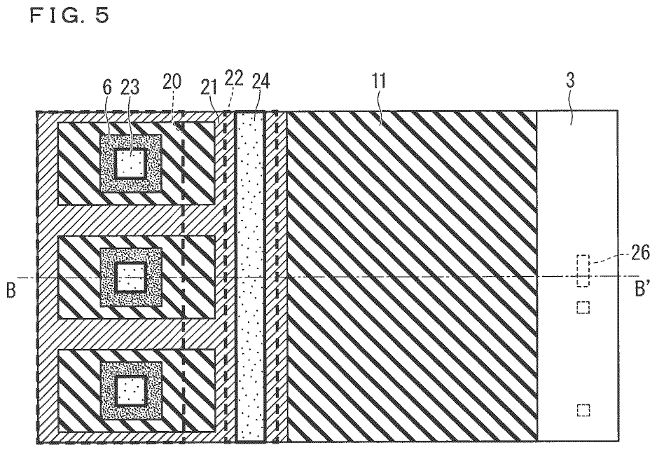

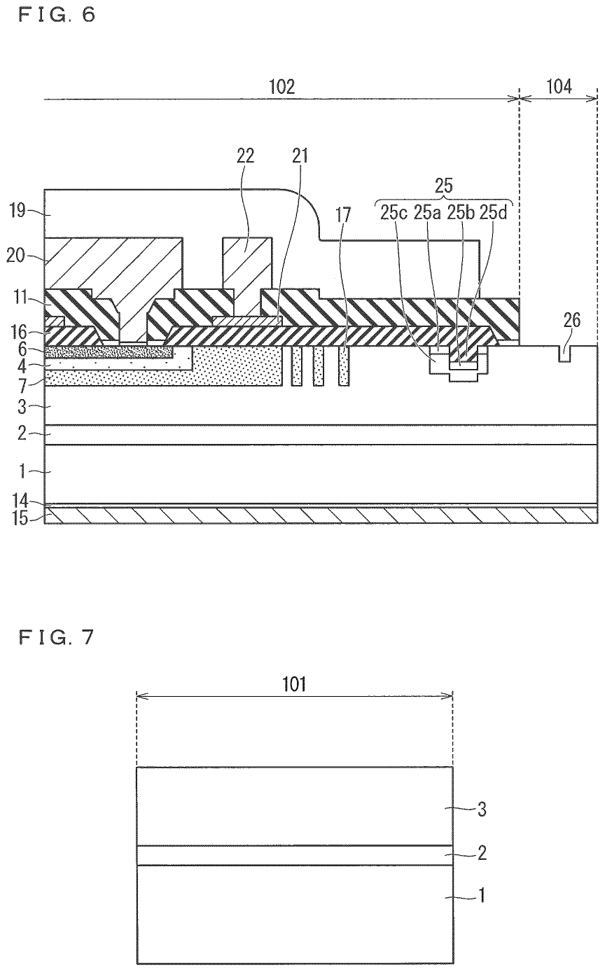

FIG. 5 is a plan view of a region corresponding to the region 106 in FIG. 1. FIG. 6 is a cross-sectional view corresponding to a cross section taken along line B-B′ in FIG. 5.

As illustrated in FIGS. 5 and 6, the semiconductor device includes the n+ substrate 1, the n+ buffer layer 2, the n-drift layer 3, the p well layer 7 formed on a surface layer of the n-drift layer 3, a pFLR diffusion layer 17 formed on a surface layer of the n-drift layer 3 on the termination region 102 side while being separated from the p well layer 7, the p channel doped layer 4 formed on a surface layer of the p well layer 7, the p+ contact layer 6 formed on a surface layer of the p channel doped layer 4, an n channel stop portion 25 formed on a surface layer of the n-drift layer 3 on the termination region 102 side while being separated from the pFLR diffusion layer 17, a field insulating film 16 formed to cover the p+ contact layer 6, the p channel doped layer 4, the p well layer 7, the pFLR diffusion layer 17, and the n channel stop portion 25, a mark groove portion 26 formed in a surface layer of the n-drift layer 3 in the dicing line region 104, a gate wiring 21 (polysilicon) partially formed on an upper surface of the field insulating film 16, the interlayer insulating film 11 formed to partially cover the gate wiring 21, a source electrode 20 (boundary portion) adjacent to the p+ contact layer 6 exposed from the interlayer insulating film 11 with the silicide layer 12 interposed between them, a gate wiring portion 22 formed to cover the gate wiring 21 exposed from the interlayer insulating film 11, a protective film 19 (polyimide) formed to cover the source electrode 20 and the gate wiring portion 22, the silicide layer 14, and the drain electrode 15. In FIG. 5, the source contact region 23 and a gate contact region 24 are illustrated.

The n channel stop portion 25 is provided on the inner side of an outer end portion of the termination region 102 (boundary with the dicing line region 104), and includes a channel stop groove portion 25d formed to reach the inside from an upper surface of the n-drift layer 3, an n type high concentration surface portion 25a, an n type high concentration bottom portion 25b, and an n type diffusion layer 25c.

The n type diffusion layer 25c is formed by diffusing into the n-drift layer 3 from a side surface and a bottom surface of the channel stop groove portion 25d. The n type high concentration surface portion 25a is formed from a top portion of the channel stop groove portion 25d (upper surface of the n-drift layer 3 outside the channel stop groove portion 25d) to a side surface. The n type high concentration surface portion 25a is formed on the surface layer of the n type diffusion layer 25c on a top portion and a side surface of the channel stop groove portion 25d. Impurity concentration of the n type high concentration surface portion 25a is higher than impurity concentration of the n-drift layer 3. The n type high concentration bottom portion 25b is formed on a bottom surface of the channel stop groove portion 25d. The n type high concentration bottom portion 25b is formed on a surface layer of the n type diffusion layer 25c on a bottom surface of the channel stop groove portion 25d. Impurity concentration of the n type high concentration bottom portion 25b is higher than impurity concentration of the n-drift layer 3. The n type diffusion layer 25c is connected to the n type high concentration surface portion 25a and the n type high concentration bottom portion 25b. Impurity concentration of the n type high concentration surface portion 25a and impurity concentration of the n type high concentration bottom portion 25b are higher than impurity concentration of the n type diffusion layer 25c.

Although one of the mark groove portions 26 is illustrated in FIG. 6, this is a part of a structural portion of a monitor or a mark, and may actually include a plurality of grooves or layers.

As illustrated in FIG. 4, a basic cell structure (unit cell) is formed in the active region 101. The source electrode 13 is formed on an upper surface (front surface) of a substrate, the drain electrode 15 is formed on a lower surface of the substrate, and main current flows in a vertical direction of the substrate. Further, a MOSFET including the n+ source layer 5, the p channel doped layer 4, the n-drift layer 3, the gate insulating film 9, and the gate electrode layer 10 performs gate control of current.

As illustrated in FIG. 3, the unit cell extends in an X axis direction and is formed in a stripe shape, and a gate wiring also extends in the X axis direction and is formed in a stripe shape.

The gate electrode layer 10 in FIG. 3 and the gate wiring 21 in FIG. 5 are connected in an outer end portion of the active region 101. The gate wiring 21 is connected to the gate wiring portion 22 in the gate contact region 24. The gate wiring portion 22 is connected to the gate pad region 103.

In the termination region 102, a withstand voltage retention structure called a FLR structure including the pFLR diffusion layer 17 and the n channel stop portion 25 is formed.

In the structure shown in the present preferred embodiment, the n type high concentration surface portion 25a and the n type high concentration bottom portion 25b are formed in the channel stop groove portion 25d.

Further, in the structure described in the present preferred embodiment, the n type diffusion layer 25c is further formed on a side surface of the channel stop groove portion 25d, and the n type high concentration surface portion 25a, the n type high concentration bottom portion 25b, and the n type diffusion layer 25c, which are diffusion layers higher in concentration than the n-drift layer 3, are electrically connected. The n channel stop portion 25 is formed in an annular shape surrounding the active region 101 in plan view.

Further, in the structure illustrated in the present preferred embodiment, the mark groove portion 26 having the same depth as the channel stop groove portion 25d is formed in the dicing line region 104. However, depth of the channel stop groove portion 25d and depth of the mark groove portion 26 only need be equal as grooves formed in the same step, and the depths may vary depending on a formation location. In other words, the depths may be different to an extent of a difference (tolerance) in depth that may occur as depth of grooves formed in the same step. The mark groove portion 26 is used as a mark or a monitor necessary in a manufacturing process.

Further, in the structure shown in the present preferred embodiment, the channel stop groove portion 25d and the mark groove portion 26 can be formed simultaneously in a manufacturing process.

Further, in the structure illustrated in the present preferred embodiment, the field insulating film 16 and the interlayer insulating film 11 are formed in an upper portion of the n channel stop portion 25, and a surface of the n type high concentration surface portion 25a, which is a high concentration portion, a surface of the n type high concentration bottom portion 25b, which is a high concentration portion, and a surface of the channel stop groove portion 25d are not exposed.

Further, in the structure shown in the present preferred embodiment, no metal electrode connected to the n channel stop portion 25 is provided in the termination region 102.

### <Method of Manufacturing Semiconductor Device>

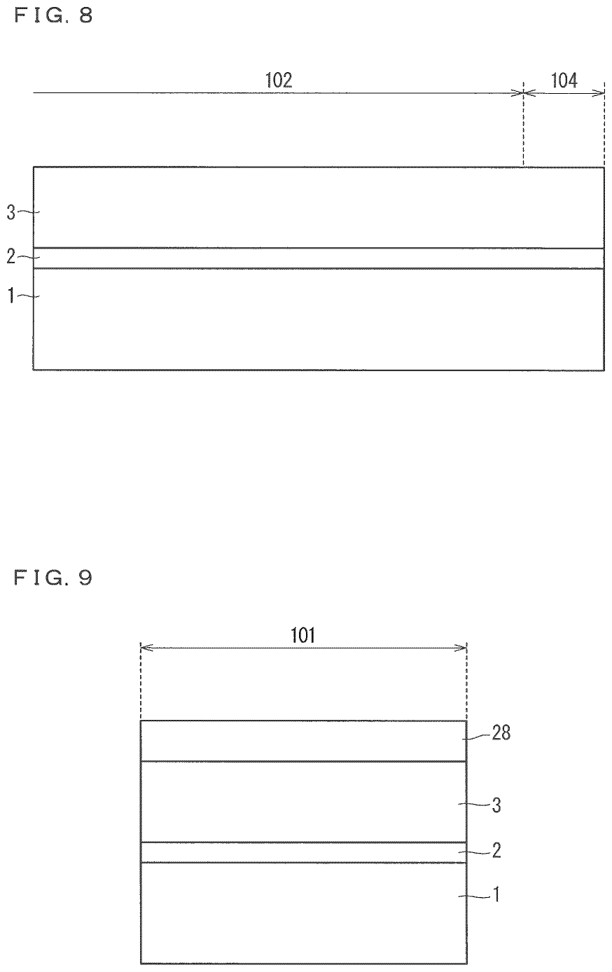

Next, a method of manufacturing a semiconductor device according to the present preferred embodiment will be described with reference to FIGS. 7 to 24. FIGS. 7 to 24 are cross-sectional views illustrating an example of the method of manufacturing a semiconductor device according to the present preferred embodiment. FIGS. 7, 9, 11, 13, 15, 17, 19, 21, and 23 correspond to a cross section taken along line A-A′ of FIG. 3. FIGS. 8, 10, 12, 14, 16, 18, 20, 22, and 24 correspond to a cross section taken along line B-B′ of FIG. 5.

FIG. 7 corresponds to a cross section taken along line A-A′ of the region 105, and FIG. 8 corresponds to a cross section taken along line B-B′ of the region 106.

As an example is illustrated in FIGS. 7 and 8, the n+ buffer layer 2 and the n-drift layer 3 are formed on an upper surface of the n+ substrate 1 (manufacturing step (a)). A structure before this can be manufactured by a standard semiconductor substrate forming technique, and thus details are omitted.

Further, in the present preferred embodiment, a substrate material is described as silicon carbide (SiC), but the substrate material can be similarly formed using a silicon (Si) material, and other materials may be applied.

Next, as an example is illustrated in FIGS. 9 and 10, after resist 28 is patterned using a general lithography technique, a region corresponding to the channel stop groove portion 25d and the mark groove portion 26 is etched by a method such as dry etching (manufacturing step (b)).

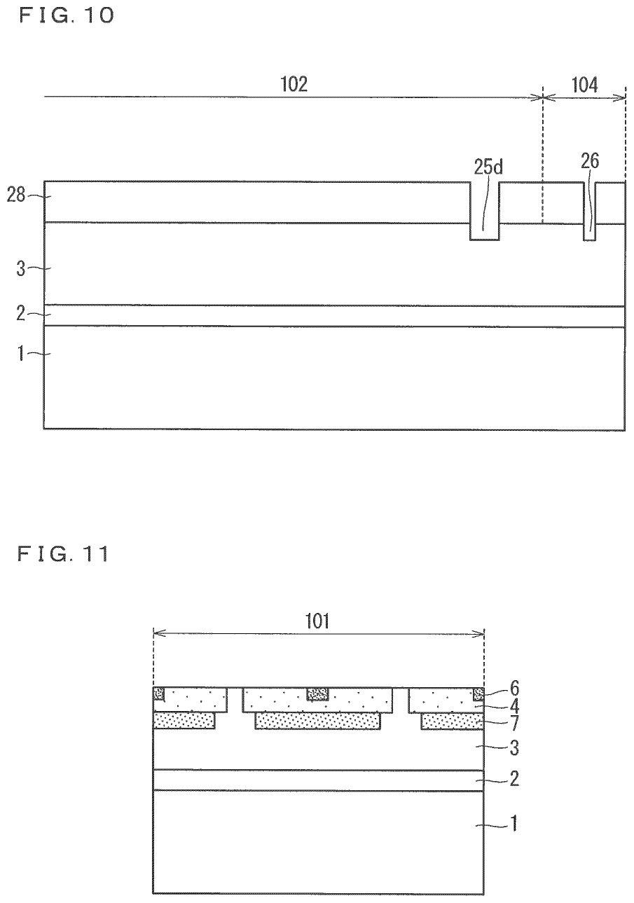

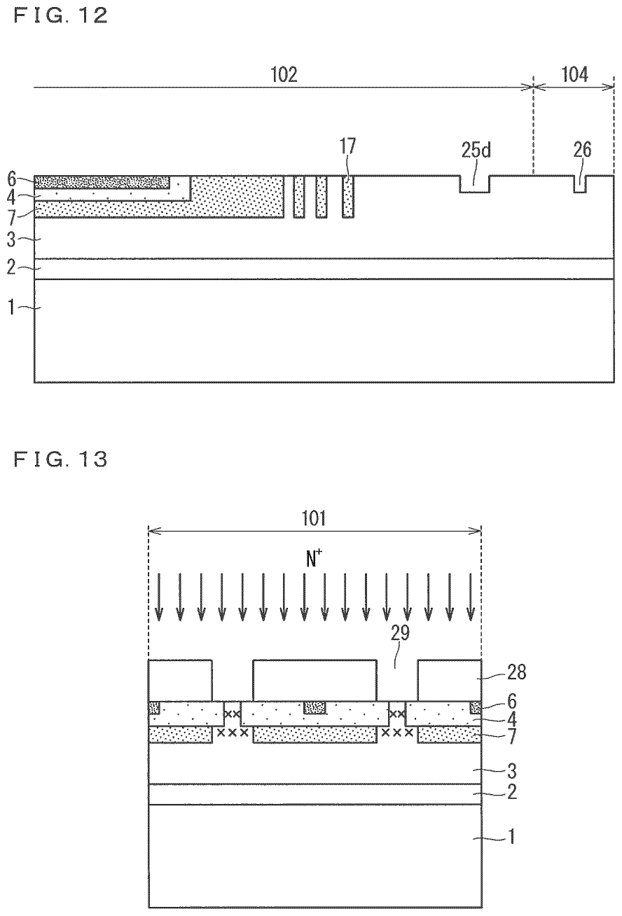

Next, as an example is illustrated in FIGS. 11 and 12, after the resist 28 is removed, the p well layer 7, the p channel doped layer 4, and the p+ contact layer 6 are formed using a lithography technique and further activated (manufacturing step (c)).

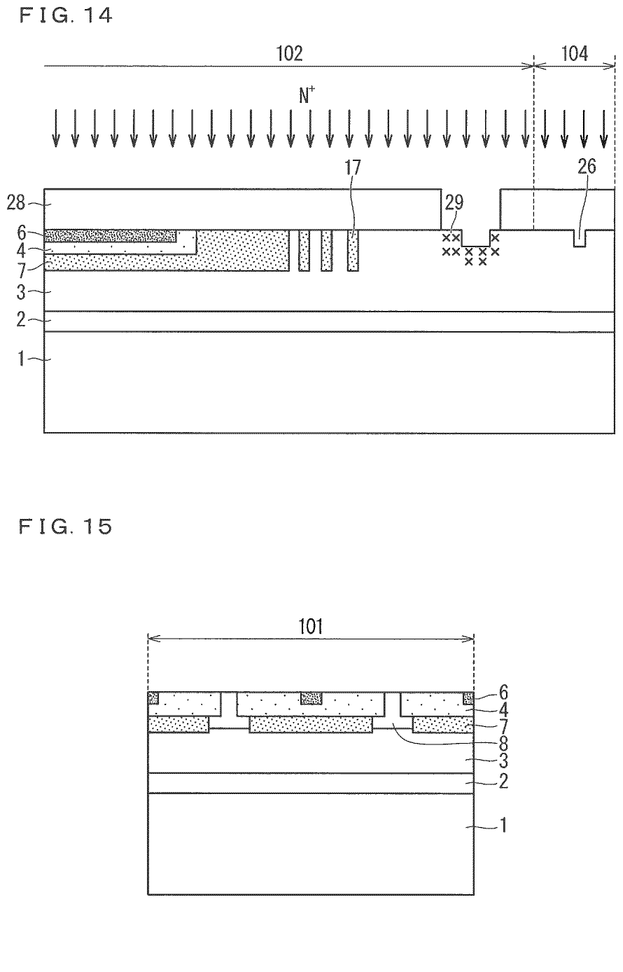

Next, as an example is illustrated in FIGS. 13 and 14, the resist 28 is patterned using a lithography technique, and n type impurities such as nitrogen (N) are implanted into a region corresponding to the nJFET doped layer 8 of the active region 101 and a region corresponding to the n type diffusion layer 25c of the termination region 102 (manufacturing step (d)).

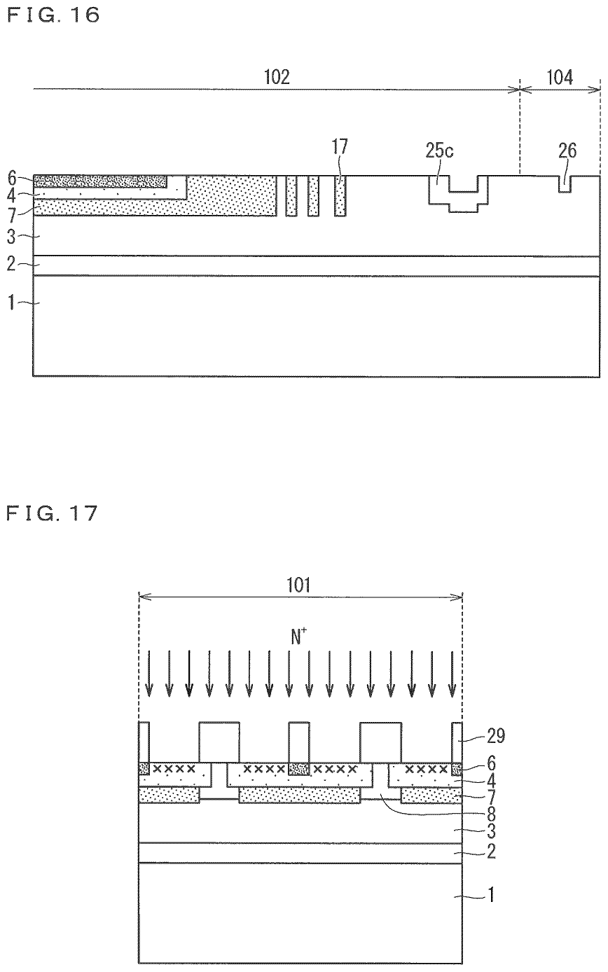

Next, as an example is illustrated in FIGS. 15 and 16, the resist 28 is removed, and annealing processing for activation is performed to form the nJFET doped layer 8 in the active region 101 and form the n type diffusion layer 25c in the termination region 102 (manufacturing step (e)).

Next, as an example is illustrated in FIGS. 17 and 18, resist 29 is patterned using a lithography technique, and n type impurities such as nitrogen (N) are implanted at a high dose into a region corresponding to the n+ source layer 5 of the active region 101 and a region corresponding to the n type high concentration surface portion 25a and the n type high concentration bottom portion 25b of the n channel stop portion 25 of the termination region 102 (manufacturing step (f)).

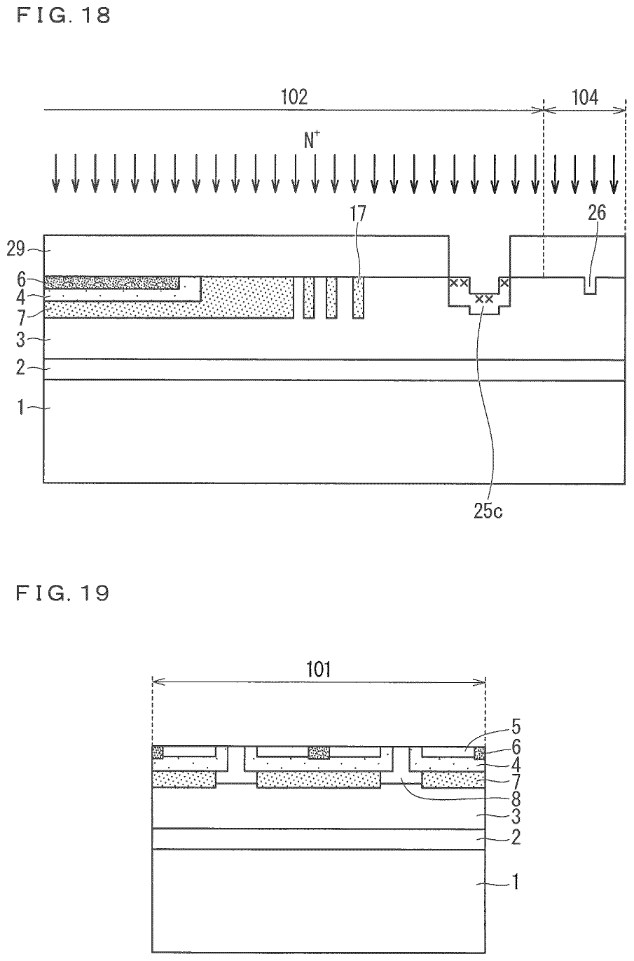

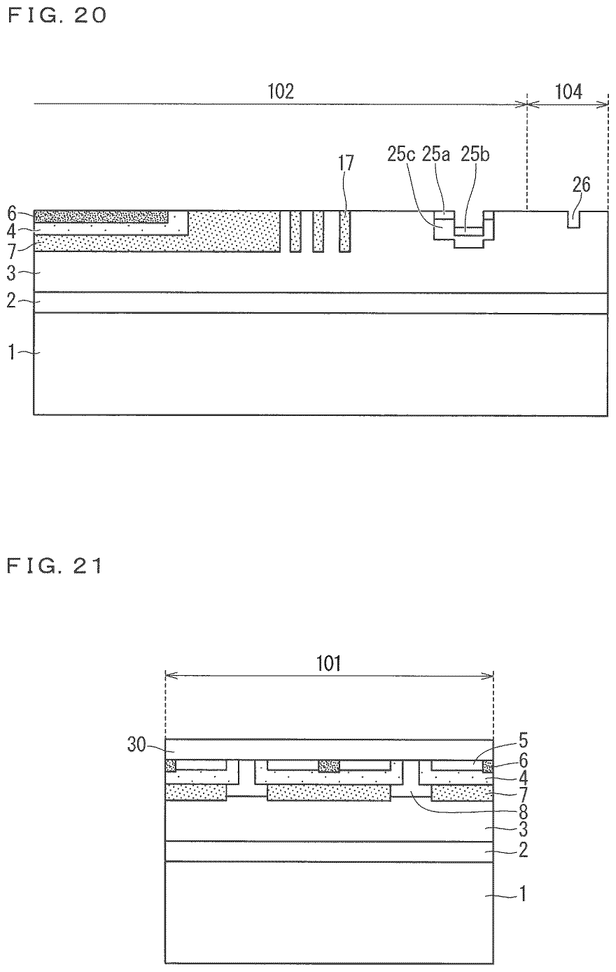

Next, as an example is illustrated in FIGS. 19 and 20, the resist 28 is removed, and activation annealing is applied to form the n+ source layer 5, the n type high concentration surface portion 25a, and the n type high concentration bottom portion 25b (manufacturing step (g)).

Although formation of a diffusion layer is completed at this stage, it is not necessary to add the annealing processing for activation for each step, and the annealing processing for activation can be performed once in the manufacturing step (g), which is at the end of the diffusion step.

Further, the manufacturing procedure may be changed, and the manufacturing step (d) or the manufacturing step (f) may be performed before or after the manufacturing step (c) or in the middle of the manufacturing step (c).

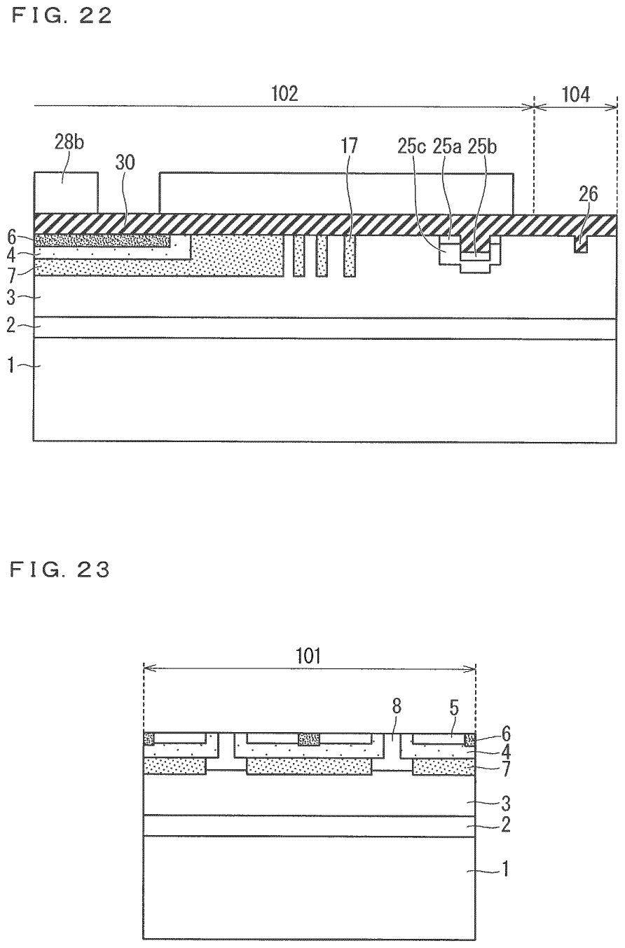

Next, as an example is illustrated in FIGS. 21 and 22, an insulating film 30 is formed on an upper surface of the n-drift layer 3 by using a method such as CVD, and resist is further patterned at a predetermined position by using a lithography technique (manufacturing step (h)). At this time, in the termination region 102, the n channel stop portion 25 is designed to be covered with resist 28b.

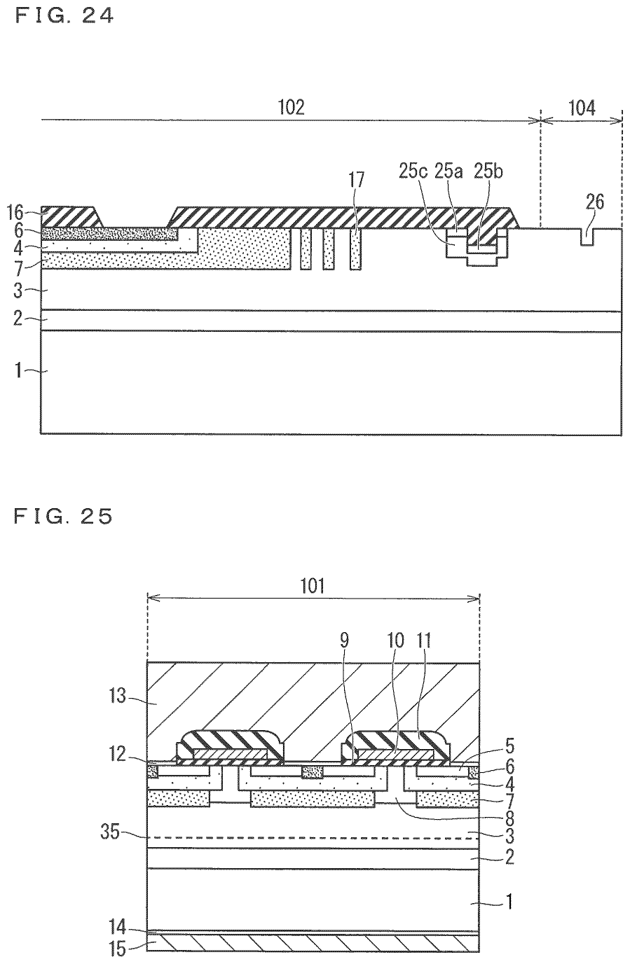

Next, as an example is illustrated in FIGS. 23 and 24, the insulating film 30 is selectively removed by using a method such as wet etching or dry etching. By this, the field insulating film 16 is formed, and the channel stop groove portion 25d is covered with the field insulating film 16 (manufacturing step (i)).

In and after this step, the structures illustrated in FIGS. 4 and 6 are formed using a general method of manufacturing a semiconductor device.

### <Regarding Operation of Semiconductor Device>

Next, operation of the semiconductor device according to the present preferred embodiment will be described.

When positive voltage is applied to the control electrode (gate pad region 103) and gate voltage equal to or more than threshold voltage of a MOSFET including the n+ source layer 5, the p channel doped layer 4, the n-drift layer 3, the gate insulating film 9, and the gate electrode layer 10 is reached, this MOSFET portion is turned on, drain voltage decreases, and main current flows between the source and the drain so that an ON state is established.

Conversely, when negative voltage is applied to the gate electrode (gate electrode layer 10) in the ON state and the gate voltage becomes equal to or less than threshold voltage, the MOSFET is turned off (closed), current between the source and the drain is cut off, and the drain voltage increases so that an OFF state is established.

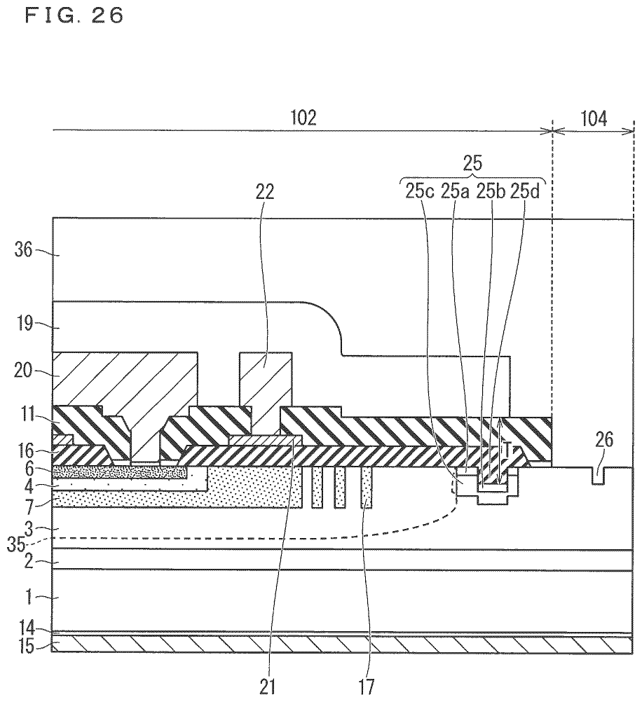

FIG. 25 is a cross-sectional view illustrating an example of a depletion layer in the cross section taken along line A-A′ of FIG. 3. FIG. 26 is a cross-sectional view illustrating an example of a depletion layer in a cross section taken along line B-B′ of FIG. 5.

In the OFF state in which withstand voltage is retained, as illustrated in the examples of FIGS. 25 and 26, the depletion layer extends toward the drain electrode side in a form indicated by a dotted line 35 according to applied voltage, and in the termination region 102, when applied voltage increases, depletion proceeds from an end portion of the active region 101 toward the outside.

Here, if the n channel stop portion 25 of the same impurity type (conductivity type) as that of the n-drift layer 3 is heavily doped, the surface cannot be depleted, so that a depletion layer shape is obtained as indicated by the dotted line 35 in FIG. 26, and the n channel stop portion 25 can suppress the extension of the depletion layer.

The above-described effect of the n channel stop portion 25 may decrease in a case where impurity concentration is low, in a case where formation width is narrow, in a case where formation depth is shallow, or the like.

On the other hand, in the present preferred embodiment, since the n channel stop portion 25 has the channel stop groove portion 25d, and has the n type high concentration surface portion 25a and the n type high concentration bottom portion 25b, impurity concentration, formation width, and formation depth are formed so as to enhance the effect of the n channel stop portion 25. For this reason, the extension of the depletion layer can be effectively suppressed.

Furthermore, in the n channel stop portion 25, the n type high concentration surface portion 25a and the n type high concentration bottom portion 25b, which are high concentration regions, are formed on a surface layer of the n type diffusion layer 25c, which is a region having higher concentration than the n-drift layer 3, and both formation width and formation depth are formed so as to enhance the effect of the n channel stop portion 25. For this reason, the extension of the depletion layer can be effectively suppressed, and withstand voltage of the semiconductor device can be stabilized.

With these structures, a position of the n channel stop portion 25 can be brought close to the active region 101 side. Therefore, chip size can be reduced, and manufacturing cost of the chip can be reduced.

In the present preferred embodiment, the n type high concentration surface portion 25a, the n type high concentration bottom portion 25b, and the n type diffusion layer 25c are formed simultaneously with the n+ source layer 5 or the nJFET doped layer 8, and their impurity concentrations cannot be set independently, but when the n type high concentration surface portion 25a and the n type high concentration bottom portion 25b have impurity concentration (surface concentration) of 1×10¹⁸/cm³ or more and 1×10²¹/cm³ or less, the effect of suppressing extension of the depletion layer and the effect of reducing ON-resistance of the MOSFET are enhanced. Further, when impurity concentration of the n type diffusion layer 25c is set between 1×10¹⁷/cm³ or more and 1×10¹⁹/cm³ or less, the ON-resistance of the MOSFET can be reduced, decrease in withstand voltage of the semiconductor device can be suppressed, and a balanced design can be made.

Further, since the channel stop groove portion 25d is formed simultaneously with the mark groove portion 26, manufacturing cost can be reduced. The mark groove portion 26 can be used as, for example, a mark for alignment of a wafer at the time of manufacturing, a mark for measuring film thickness of a film stacked on a bottom portion, a character for recognition, or the like. These marks are formed in the dicing line region 104 to which an electric field is not strongly applied when voltage is applied.

Depth of the channel stop groove portion 25d of the n channel stop portion 25 in the present preferred embodiment cannot be determined by the channel stop groove portion 25d alone since it is formed simultaneously with the mark groove portion 26, but the effect of the n channel stop portion 25 can be enhanced by adjusting depth of the n type diffusion layer 25c to be deeper than the channel stop groove portion 25d.

Further, in the present preferred embodiment, an upper portion of the n channel stop portion 25 is covered with the field insulating film 16, and the n type high concentration surface portion 25a and the n type high concentration bottom portion 25b are not exposed. Further, since an insulating film (the field insulating film 16 and the interlayer insulating film 11) on an upper portion of the channel stop groove portion 25d is formed thick, a metal electrode electrically connected to the n channel stop portion 25 is not formed at an end portion of the termination region 102.

Further, since upper surfaces of the n type high concentration surface portion 25a and the n type high concentration bottom portion 25b are not exposed, moisture does not come into direct contact with an upper surface of a substrate, and it is possible to suppress peeling of a structural portion due to generation of an oxide-based product by reaction of the upper surface.

Furthermore, in the channel stop groove portion 25d, since thickness T of the insulating film is greater than another portion (upper surface of the n-drift layer 3 outside the channel stop groove portion 25d) covered with an insulating film (the field insulating film 16 and the interlayer insulating film 11), electric field intensity in the channel stop groove portion 25d including the inside of the channel stop groove portion 25d is lower than that in a peripheral region. For this reason, generation of an oxide-based product at the portion is suppressed, and peeling of a structural portion and destruction of an element accompanying it can be suppressed.

Further, since a metal electrode electrically connected to the n channel stop portion 25 is not formed, a problem that metal corrodes at the connection portion and peeling of a structural portion is accelerated does not occur. Therefore, moisture resistance can be improved.

### Second Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

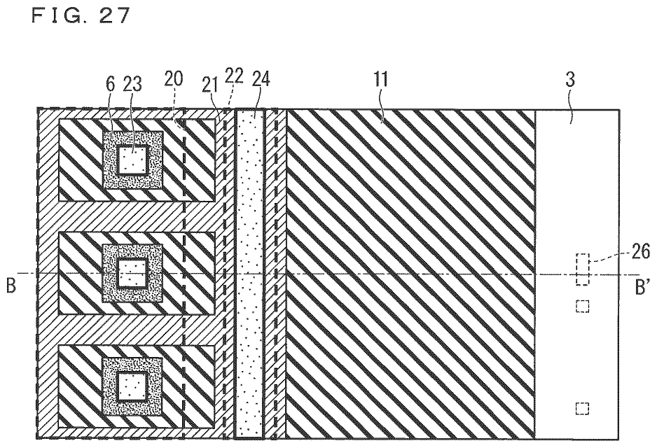

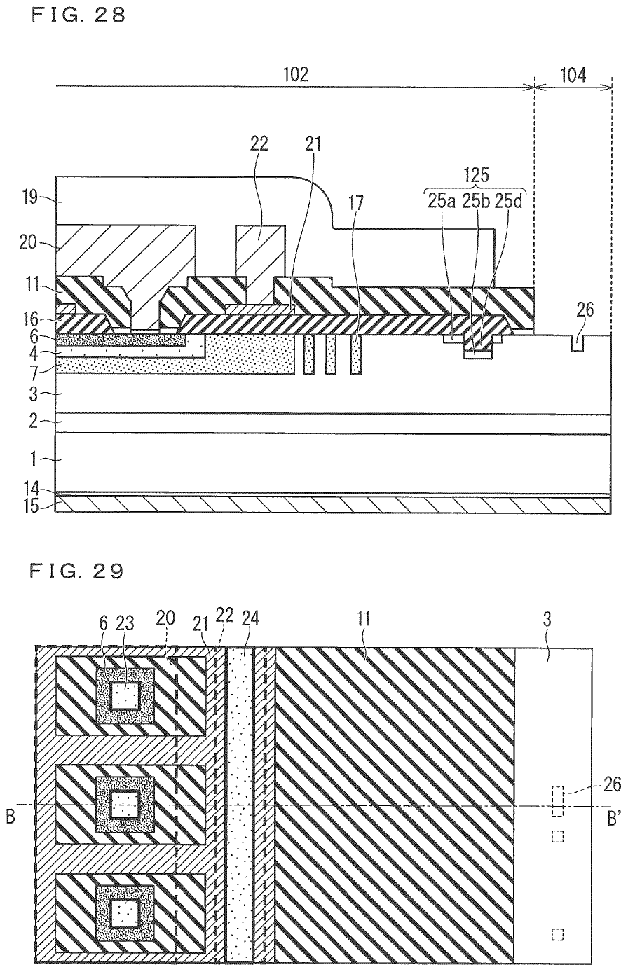

FIG. 27 is a plan view of a region corresponding to the region 106 in FIG. 1 relating to the present preferred embodiment. FIG. 28 is a cross-sectional view corresponding to a cross section taken along line B-B′ in FIG. 27. Since a configuration in the element region 100 and a configuration in the active region 101 are the same as those shown in the first preferred embodiment, detailed description of the configurations will be omitted.

The present preferred embodiment is the same as the first preferred embodiment in that an n channel stop portion 125 includes the channel stop groove portion 25d, the n type high concentration surface portion 25a, and the n type high concentration bottom portion 25b, but is different in that the n type diffusion layer 25c is not formed. Depth of the channel stop groove portion 25d is greater than thickness in a depth direction of the n type high concentration surface portion 25a and thickness in a depth direction of the n type high concentration bottom portion 25b.

Further, as in the case of the first preferred embodiment, the mark groove portion 26 having the same depth as the channel stop groove portion 25d is formed in the dicing line region 104, and is used as a mark or a monitor necessary for a manufacturing process, and these two portions are simultaneously formed in the manufacturing process.

Furthermore, as in the first preferred embodiment, the field insulating film 16 and the interlayer insulating film 11 are formed on an upper portion of the n channel stop portion 125, a surface of the n type high concentration surface portion 25a as a high concentration portion, a surface of the n type high concentration bottom portion 25b as a high concentration portion, and a surface of the channel stop groove portion 25d are not exposed, and the termination region 102 is not provided with a metal electrode connected to the n channel stop portion 125.

The effect generated due to the same configuration as that of the first preferred embodiment is described in the first preferred embodiment, and will be omitted from detailed description.

In the present preferred embodiment, the n type high concentration surface portion 25a as a high concentration portion is formed at a top portion of the channel stop groove portion 25d and the n type high concentration bottom portion 25b as a high concentration portion is formed at a bottom portion of the channel stop groove portion 25d, it is possible to effectively suppress extension of the depletion layer.

Depth of the channel stop groove portion 25d is shared with the mark groove portion 26 and it needs to be formed in balance, but in consideration of that optical detection can be performed using it as a mark and suppression of extension of the depletion layer, both can be realized by setting the depth of the channel stop groove portion 25d to 0.3 μm or more and 5.0 μm or less.

As described above, also in the present preferred embodiment, it is possible to realize stable suppression on extension of the depletion layer in the n channel stop portion 125 and improvement in moisture resistance while suppressing increase in manufacturing cost for forming the channel stop groove portion 25d by using a flow common to formation of marks.

### Third Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

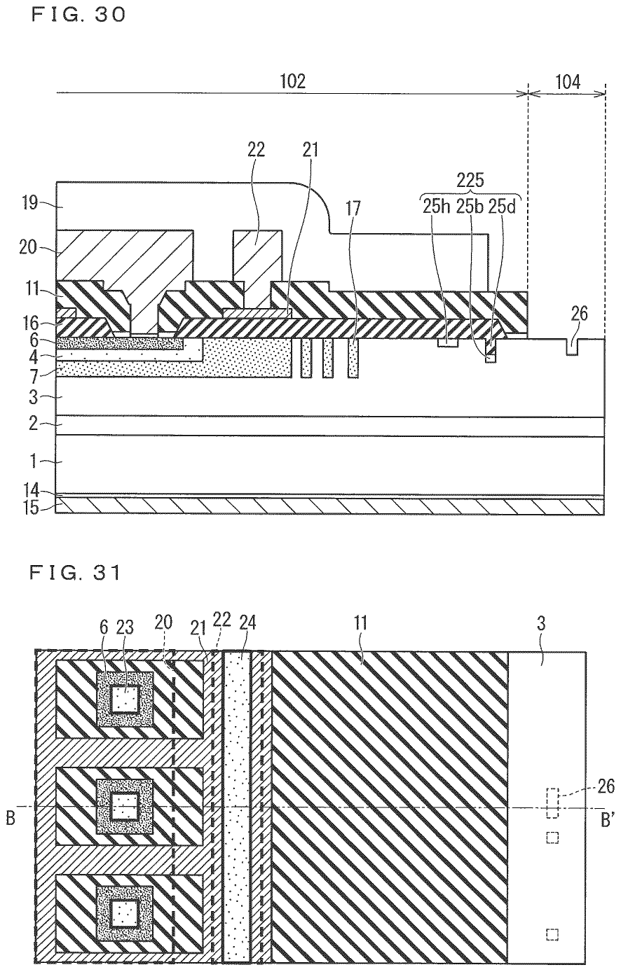

FIG. 29 is a plan view of a region corresponding to the region 106 in FIG. 1 relating to the present preferred embodiment. FIG. 30 is a cross-sectional view corresponding to a cross section taken along line B-B′ in FIG. 29. Since a configuration in the element region 100 and a configuration in the active region 101 are the same as those shown in the first preferred embodiment, detailed description of the configurations will be omitted.

In the present preferred embodiment, the channel stop groove portion 25d and the n type high concentration bottom portion 25b of an n channel stop portion 225 are annularly formed on the outer side (direction away from the active region 101) of a standard n channel stop layer (n type high concentration surface portion 25h) formed on a surface layer of the n-drift layer 3. The n channel stop portion 225 includes the n type high concentration surface portion 25h, the channel stop groove portion 25d, and the n type high concentration bottom portion 25b.

Further, as in the case of the first preferred embodiment, the mark groove portion 26 having the same depth as the channel stop groove portion 25d is formed in the dicing line region 104, and is used as a mark or a monitor necessary for a manufacturing process, and these two portions are simultaneously formed in the manufacturing process.

Furthermore, similarly to the case of the first preferred embodiment, the field insulating film 16 and the interlayer insulating film 11 are formed on an upper portion of the n channel stop portion 225, a surface of the n type high concentration bottom portion 25b as a high concentration portion and a surface of the channel stop groove portion 25d are not exposed, and the termination region 102 is not provided with a metal electrode connected to the n channel stop portion 225.

The effect generated due to the same configuration as that of the first preferred embodiment is described in the first preferred embodiment, and will be omitted from detailed description.

In the present preferred embodiment, since an effect of suppressing extension of the depletion layer by a standard n channel stop layer (the n type high concentration surface portion 25h) can be generated, the effect can be effectively enhanced by the n channel stop portion 225.

### Fourth Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

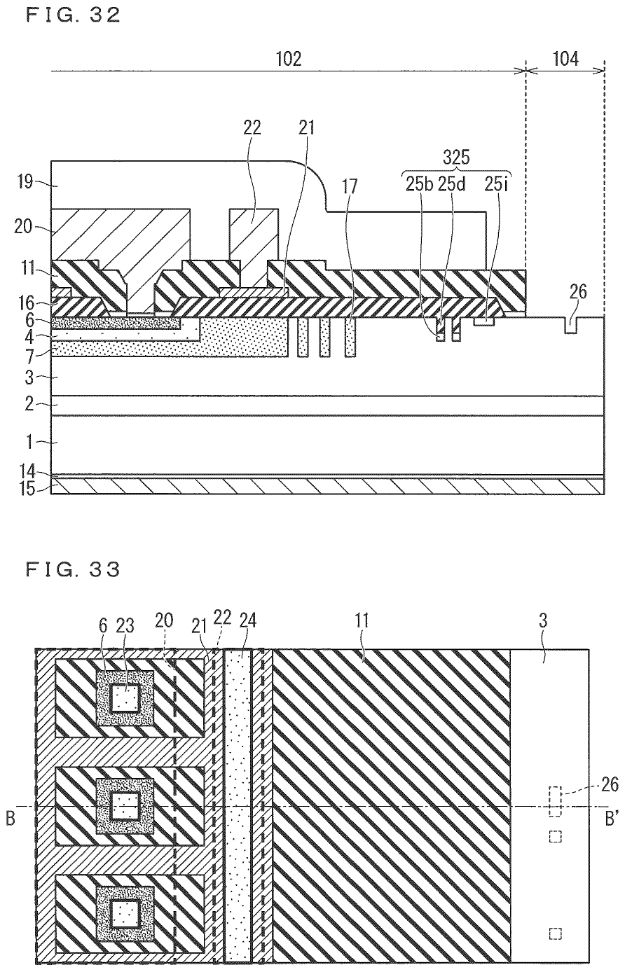

FIG. 31 is a plan view of a region corresponding to the region 106 in FIG. 1 relating to the present preferred embodiment. FIG. 32 is a cross-sectional view corresponding to a cross section taken along line B-B′ in FIG. 31. Since a configuration in the element region 100 and a configuration in the active region 101 are the same as those shown in the first preferred embodiment, detailed description of the configurations will be omitted.

In the present preferred embodiment, the channel stop groove portion 25d and the n type high concentration bottom portion 25b of an n channel stop portion 325 are annularly formed on the inner side (direction approaching the active region 101) of a standard n channel stop layer (n type high concentration surface portion 25i) formed on a surface layer of the n-drift layer 3. The n channel stop portion 325 includes the n type high concentration surface portion 25i, the channel stop groove portion 25d, and the n type high concentration bottom portion 25b.

Furthermore, as illustrated in FIG. 32, a plurality of the channel stop groove portions 25d may be formed in the n channel stop portion 325, and the n type high concentration bottom portion 25b may be formed at a bottom portion of each of the channel stop groove portions 25d.

By configuring the n channel stop portion 325 with a plurality of narrow grooves (the channel stop groove portions 25d), it is possible to improve embeddability inside the channel stop groove portions 25d. Therefore, it is possible to expect the effect of suppressing extension of the depletion layer and improvement of moisture resistance by relaxing an electric field of the insulating film (the field insulating film 16 and the interlayer insulating film 11) in an upper portion of the channel stop groove portion 25d.

In the present preferred embodiment, the n type high concentration surface portion 25a and the n type diffusion layer 25c are not formed, but by forming them, the effect of suppressing extension of the depletion layer can be further enhanced.

### Fifth Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

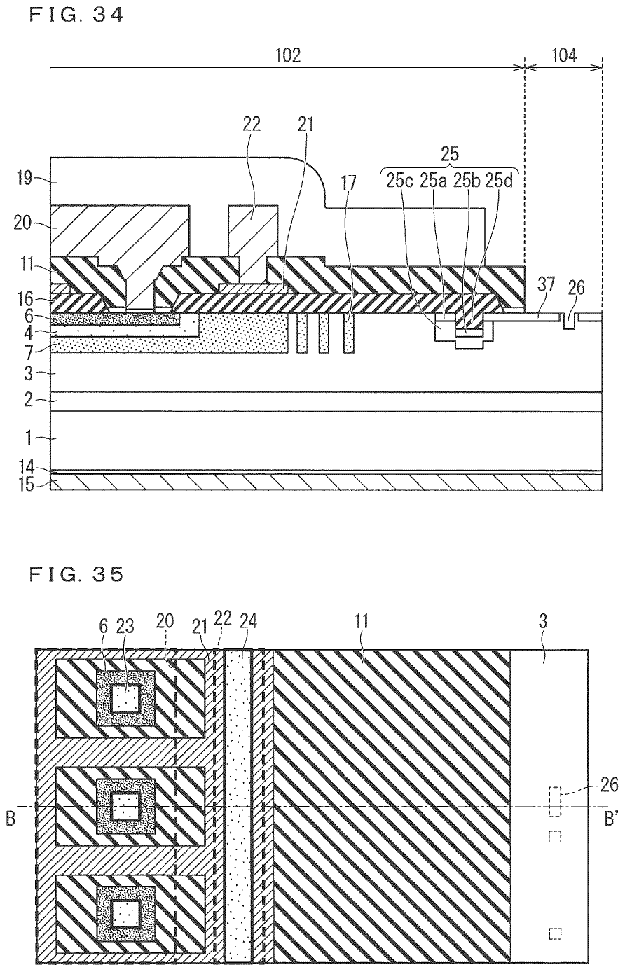

FIG. 33 is a plan view of a region corresponding to the region 106 in FIG. 1 relating to the present preferred embodiment. FIG. 34 is a cross-sectional view corresponding to a cross section taken along line B-B′ in FIG. 33. Since a configuration in the element region 100 and a configuration in the active region 101 are the same as those shown in the first preferred embodiment, detailed description of the configurations will be omitted.

In the present preferred embodiment, the n channel stop portion 25 is formed similarly to the case shown in the first preferred embodiment, and an n+ diffusion layer 37 of the same impurity type (conductivity type) as the n-drift layer 3 is also formed on a surface layer of the n-drift layer 3 in the dicing line region 104.

Note that, since there is a possibility that a portion (the mark groove portion 26) that becomes an alignment mark or monitors of the dicing line region 104 cannot become an alignment mark or monitors by ion implantation, the n+ diffusion layer 37 is not formed at the portion.

Also in the present preferred embodiment, it is possible to enhance an effect of a channel stop that suppresses extension of the depletion layer.

### Sixth Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

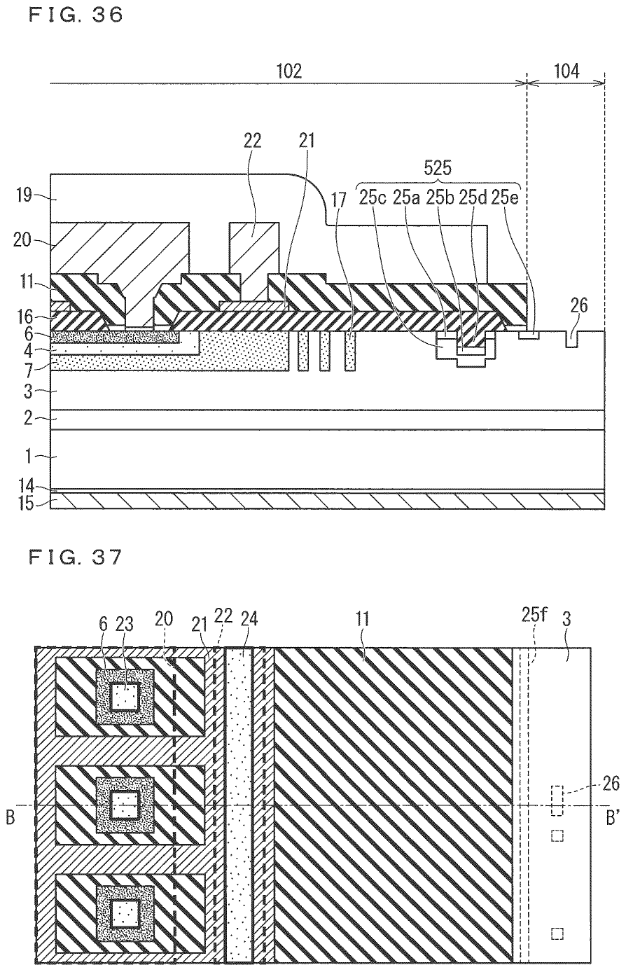

FIG. 35 is a plan view of a region corresponding to the region 106 in FIG. 1 relating to the present preferred embodiment. FIG. 36 is a cross-sectional view corresponding to a cross section taken along line B-B′ in FIG. 35. Since a configuration in the element region 100 and a configuration in the active region 101 are the same as those shown in the first preferred embodiment, detailed description of the configurations will be omitted.

The present preferred embodiment is a variation of the fifth preferred embodiment, and an n type high concentration surface portion 25e of an n channel stop portion 525 is formed on a surface layer of the n-drift layer 3 at a boundary portion between the termination region 102 and the dicing line region 104 outside the channel stop groove portion 25d (in a direction away from the active region 101). The n type high concentration surface portion 25e is formed at a position farther away from the active region 101 than the n type high concentration surface portion 25a. The n channel stop portion 525 includes the n type high concentration surface portion 25a, the n type high concentration bottom portion 25b, the n type diffusion layer 25c, the channel stop groove portion 25d, and the n type high concentration surface portion 25e.

Also in the present preferred embodiment, it is possible to enhance an effect of a channel stop that suppresses extension of the depletion layer.

### Seventh Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

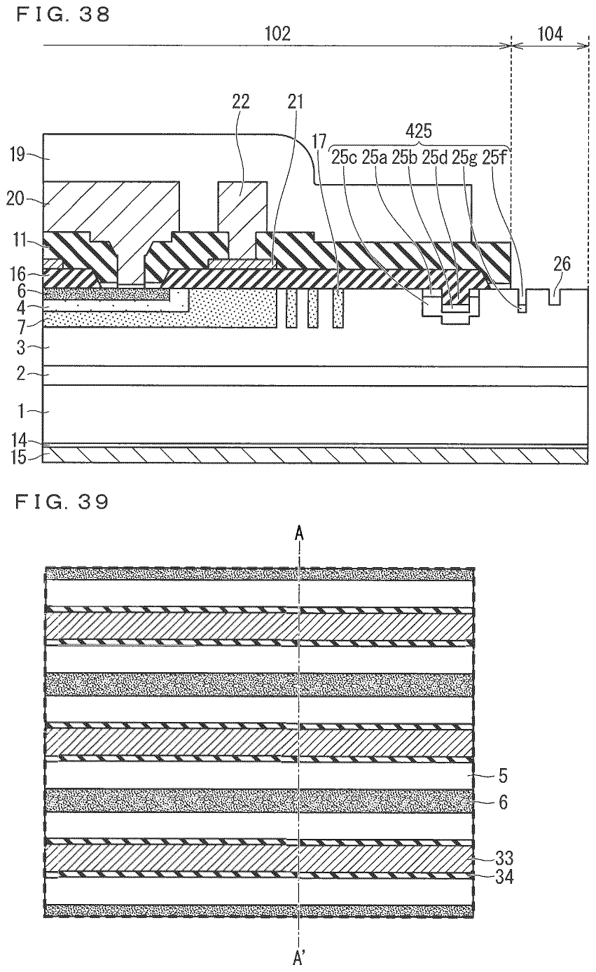

FIG. 37 is a plan view of a region corresponding to the region 106 in FIG. 1 relating to the present preferred embodiment. FIG. 38 is a cross-sectional view corresponding to a cross section taken along line B-B′ in FIG. 37. Since a configuration in the element region 100 and a configuration in the active region 101 are the same as those shown in the first preferred embodiment, detailed description of the configurations will be omitted.

In the present preferred embodiment, as compared with the preferred embodiment described in the first preferred embodiment, the dicing line region 104 at a boundary portion with the termination region 102 includes an annular channel stop groove portion 25f surrounding the active region 101 while being separated from the channel stop groove portion 25d, and an n+ high concentration bottom portion 25g formed at a bottom portion of the channel stop groove portion 25f. An n channel stop portion 425 includes the n type high concentration surface portion 25a, the n type high concentration bottom portion 25b, the n type diffusion layer 25c, the channel stop groove portion 25d, the channel stop groove portion 25f, and the n type high concentration bottom portion 25g.

Also in the present preferred embodiment, it is possible to enhance an effect of a channel stop that suppresses extension of the depletion layer. Further, by forming a groove in an annular shape by the channel stop groove portion 25f, in a case where a surface crack occurs at the time of dicing, it is possible to suppress development of the crack to the termination region 102.

### Eighth Preferred Embodiment

A semiconductor device and a method of manufacturing a semiconductor device according to the present preferred embodiment will be described. Note that, in description below, a constituent element similar to a constituent element described in the preferred embodiment described above is denoted by the same reference numeral, and will be omitted from detailed description as appropriate.

### <Regarding Configuration of Semiconductor Device>

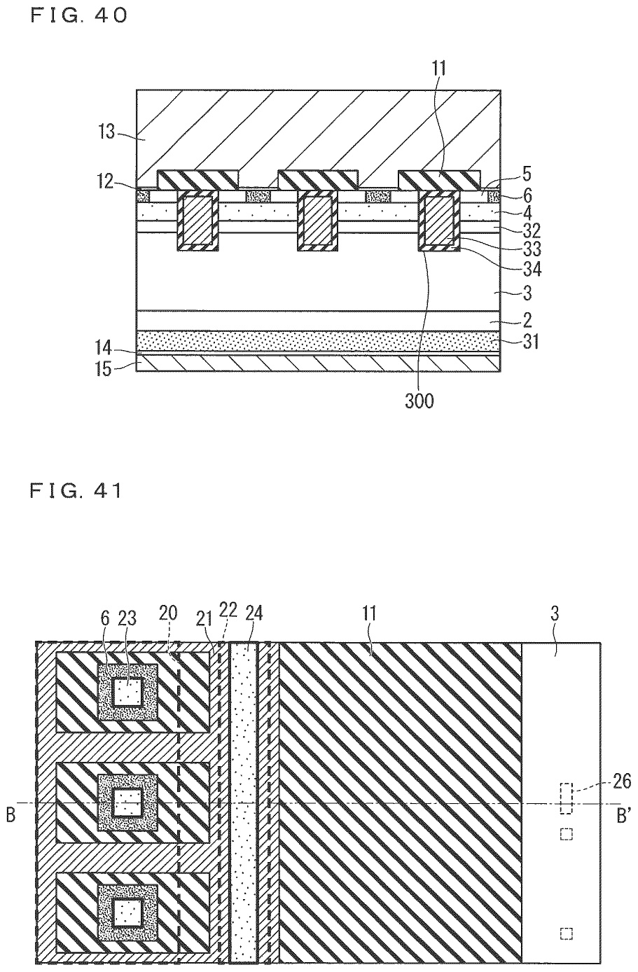

FIG. 39 is a plan view of the active region 101 corresponding to the region 105 in FIG. 1 relating to the present preferred embodiment. FIG. 40 is a cross-sectional view corresponding to a cross section taken along line A-A′ in FIG. 39.

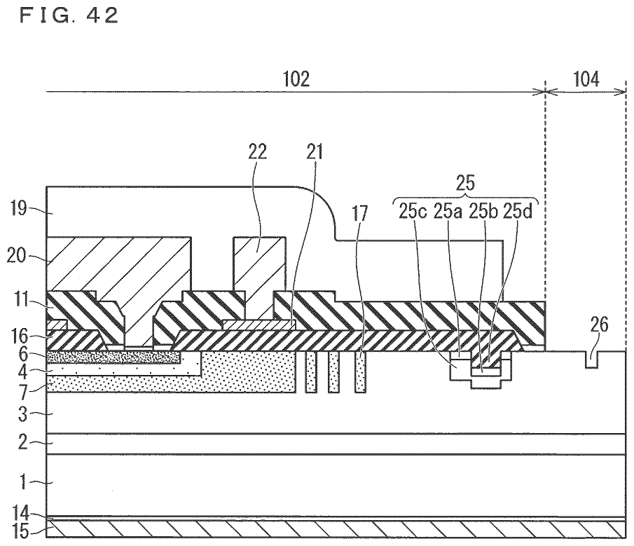

FIG. 41 is a plan view of a region corresponding to the region 106 in FIG. 1 relating to the present preferred embodiment. FIG. 42 is a cross-sectional view corresponding to a cross section taken along line B-B′ in FIG. 41.

In the present preferred embodiment, an improved structure of the termination region 102 is applied to a trench type IGBT.

In the present preferred embodiment, a trench type MOSFET is formed on the front surface (upper surface) side of the substrate, a p type collector layer 31 is formed on the back surface (lower surface) side of the substrate, and a vertical IGBT is formed as a whole.

As an example is illustrated in FIGS. 39 and 40, the semiconductor device includes, in the active region 101, the n+ buffer layer 2, the n-drift layer 3 provided on an upper surface of the n+ buffer layer 2, the p channel doped layer 4 formed on a surface layer of the n-drift layer 3, an n carrier accumulation layer 32 formed in a lower layer of the p channel doped layer 4, the n+ source layer 5 formed on a surface layer of the p channel doped layer 4, the p+ contact layer 6 formed on a surface layer of the p channel doped layer 4, a trench 300 formed so as to reach the inside of the n-drift layer 3 from an upper surface of the n+ source layer 5, a gate electrode layer 33 (polysilicon) formed in a manner surrounded by a gate insulating film 34 in the trench 300, the interlayer insulating film 11 formed to cover the gate electrode layer 33, the silicide layer 12 formed to cover the n+ source layer 5 exposed from the interlayer insulating film 11 and the p+ contact layer 6 exposed from the interlayer insulating film 11, the source electrode 13 formed to cover the interlayer insulating film 11 and the silicide layer 12, the p type collector layer 31 provided on a lower surface of the n+ buffer layer 2, the silicide layer 14 provided in a lower layer of the p type collector layer 31, and the drain electrode 15 provided on a lower surface of the silicide layer 14.

A basic configuration in the termination region 102 and the dicing line region 104 illustrated in FIGS. 41 and 42 is the same as that of another preferred embodiment, but is different from that of another preferred embodiment in that the n type high concentration surface portion 25a and the n type high concentration bottom portion 25b of the n channel stop portion 25 are formed simultaneously with the n+ source layer 5 of a trench MOSFET, and the n type diffusion layer 25c is formed simultaneously with the n carrier accumulation layer 32. However, it may be formed in another step as necessary without being formed simultaneously with these diffusion layers. Further, the trench 300 may be formed simultaneously with the channel stop groove portion 25d.

As described above, even when a cell structure in the active region 101 is changed, if a configuration of the n channel stop portion 25 is configured as in another preferred embodiment, it is possible to realize suppression on extension of the depletion layer to stabilize withstand voltage of the semiconductor device, improvement in moisture resistance, reduction in manufacturing cost by sharing of marks, or the like.

Although a plurality of the preferred embodiments are described above, the present invention is not limited to the described structure, and can be applied to another structure such as a diode, and a similar effect can be basically obtained even if polarity is inverted. Further, as for a material, it can also be applied to silicon, silicon carbide, gallium nitride, and the like.

### <Regarding Effect Generated by Plurality of Preferred Embodiments Described Above>

Next, an example of an effect generated by a plurality of the preferred embodiments described above will be described. Note that, in description below, the effect will be described based on a specific configuration exemplified in a plurality of the preferred embodiments described above, but the configuration may be replaced with another specific configuration exemplified in the present description as long as a similar effect is generated. That is, hereinafter, for convenience, only one of associated specific configurations may be described as a representative, but the specific configuration described as a representative may be replaced with another specific configuration associated.

Further, the replacement may be performed across a plurality of preferred embodiments. That is, the case may be such that a similar effect is generated by combination of configurations exemplified in different preferred embodiments.

According to the preferred embodiment described above, the semiconductor device includes the active region 101 in which an element structure is formed, and the termination region 102 surrounding the active region 101 in plan view. The semiconductor device includes a semiconductor layer of a first conductivity type and the n channel stop portion 25 (alternatively, the n channel stop portion 125, the n channel stop portion 225, the n channel stop portion 325, the n channel stop portion 425, and the n channel stop portion 525). Here, the semiconductor layer corresponds to, for example, the n-drift layer 3 or the like. The n-drift layer 3 is provided in the active region 101 and the termination region 102. The n channel stop portion 25 is provided inside an outer end portion of the termination region 102. The n channel stop portion 25 includes a first channel stop groove portion formed to reach the inside from an upper surface of the n-drift layer 3, a first impurity portion of a first conductivity type formed on a surface layer of the n-drift layer 3 outside the first channel stop groove portion, and a second impurity portion of the first conductivity type formed in a bottom portion of the first channel stop groove portion. Here, the first channel stop groove portion corresponds to, for example, the channel stop groove portion 25d or the like. Further, the first impurity portion corresponds to, for example, the n type high concentration surface portion 25a, the n type diffusion layer 25c, the n type high concentration surface portion 25e, the n type high concentration surface portion 25h, the n type high concentration surface portion 25i, and the like. Further, the second impurity portion corresponds to, for example, the n type high concentration bottom portion 25b, the n type diffusion layer 25c, the n type high concentration bottom portion 25g, and the like. Impurity concentration of the n type high concentration surface portion 25a and impurity concentration of the n type high concentration bottom portion 25b are higher than impurity concentration of the n-drift layer 3.

According to such a configuration, it is possible to suppress extension of the depletion layer from the n channel stop portion 25 to an end portion of a chip, so that withstand voltage of the semiconductor device is stabilized and reliability is improved.

Note that, even in a case where another configuration exemplified in the present description is appropriately added to the above configuration, that is, even in a case where another configuration in the present description not mentioned as the above configuration is appropriately added, a similar effect can be generated.

Further, according to the preferred embodiment described above, the n channel stop portion 25 (alternatively, the n channel stop portion 425 and the n channel stop portion 525) includes a third impurity portion of the first conductivity type formed on a side surface of the channel stop groove portion 25d. Here, the third impurity portion corresponds to, for example, the n type diffusion layer 25c or the like. According to such a configuration, it is possible to suppress extension of the depletion layer from the n channel stop portion 25 to an end portion of a chip, so that withstand voltage of the semiconductor device is stabilized and reliability is improved.

Further, according to the preferred embodiment described above, the n type diffusion layer 25c is connected to the n type high concentration surface portion 25a and the n type high concentration bottom portion 25b. According to such a configuration, it is possible to suppress extension of the depletion layer from the n channel stop portion 25 to an end portion of a chip, so that withstand voltage of the semiconductor device is stabilized and reliability is improved.

Further, according to the preferred embodiment described above, impurity concentration of the n type high concentration surface portion 25a and impurity concentration of the n type high concentration bottom portion 25b are higher than impurity concentration of the n type diffusion layer 25c. According to such a configuration, the n type high concentration surface portion 25a formed on a surface layer of the n-drift layer 3 and the n type high concentration bottom portion 25b formed on a bottom surface of the channel stop groove portion 25d can suppress extension of the depletion layer from the n channel stop portion 25 to an end portion of a chip, so that withstand voltage of the semiconductor device is stabilized and reliability is improved.

According to the preferred embodiment described above, impurity concentration of the n type high concentration surface portion 25a and impurity concentration of the n type high concentration bottom portion 25b are 1×10¹⁸/cm³ or more and 1×10²¹/cm³ or less. According to such a configuration, the n type high concentration surface portion 25a formed on a surface layer of the n-drift layer 3 and the n type high concentration bottom portion 25b formed on a bottom surface of the channel stop groove portion 25d can suppress extension of the depletion layer from the n channel stop portion 25 to an end portion of a chip, so that withstand voltage of the semiconductor device is stabilized and reliability is improved.

Further, according to the preferred embodiment described above, the semiconductor device includes the dicing line region 104 surrounding the termination region 102 in plan view. The n-drift layer 3 is provided in the dicing line region 104. Further, the semiconductor device includes an outer groove portion formed to reach the inside from an upper surface of the n-drift layer 3 in the dicing line region 104. Here, the outer groove portion corresponds to, for example, the mark groove portion 26. Then, depth of the mark groove portion 26 is equal to depth of the channel stop groove portion 25d. According to such a configuration, it is possible to suppress extension of the depletion layer from the n channel stop portion 25 to an end portion of a chip, so that withstand voltage of the semiconductor device is stabilized and reliability is improved. Further, by simultaneously forming the channel stop groove portion 25d and the mark groove portion 26, the number of steps can be reduced.

Further, according to the preferred embodiment described above, no metal electrode is provided in an upper portion of the n channel stop portion 25. According to such a configuration, it is possible to suppress decrease in temperature humidity bias (THB) tolerance caused by corrosion of an electrode.

Further, according to the preferred embodiment described above, an upper portion of the n channel stop portion 25 is covered with an insulating film without a conductive material interposed between them. Here, the insulating film corresponds to, for example, the field insulating film 16 or the like. According to such a configuration, adhesion to a mold material can be improved.

Further, according to the preferred embodiment described above, thickness of the field insulating film 16 in an upper portion of the channel stop groove portion 25d is larger than thickness of the field insulating film 16 outside the channel stop groove portion 25d. According to such a configuration, moisture resistance of the semiconductor device can be improved.

Further, according to the preferred embodiment described above, the n channel stop portion 425 includes a second channel stop groove portion formed apart from the channel stop groove portion 25d at a position farther away from the active region 101 than the channel stop groove portion 25d, and a fourth impurity portion of the first conductivity type formed at a bottom portion of the second channel stop groove portion. Here, the second channel stop groove portion corresponds to, for example, the channel stop groove portion 25f. Further, the fourth impurity portion corresponds to, for example, the n type high concentration bottom portion 25g. Impurity concentration of the n type high concentration bottom portion 25g is higher than impurity concentration of the n-drift layer 3. According to such a configuration, it is possible to suppress extension of the depletion layer from the n channel stop portion to an end portion of a chip, so that withstand voltage of the semiconductor device is stabilized and reliability is improved.

Further, according to the preferred embodiment described above, the n channel stop portion 525 includes a fifth impurity portion of the first conductivity type formed on a surface layer of the n-drift layer 3 at a position farther from the active region 101 than the n type high concentration surface portion 25a. Here, the fifth impurity portion corresponds to, for example, the n type high concentration surface portion 25e or the like. Impurity concentration of the n type high concentration surface portion 25e is higher than impurity concentration of the n-drift layer 3. According to such a configuration, it is possible to suppress extension of the depletion layer from the n channel stop portion to an end portion of a chip, so that withstand voltage of the semiconductor device is stabilized and reliability is improved.

Further, according to the preferred embodiment described above, the semiconductor device includes a trench type MOSFET provided in the active region 101. Then, depth of the trench 300 in the trench type MOSFET is equal to depth of the channel stop groove portion 25d. According to such a configuration, it is possible to suppress extension of the depletion layer from the n channel stop portion 25 to an end portion of a chip, so that withstand voltage of the semiconductor device is stabilized and reliability is improved.

Further, according to the preferred embodiment described above, the n-drift layer 3 is made from silicon carbide. According to such a configuration, a silicon carbide substrate with a high material cost can be efficiently formed.

According to the preferred embodiment described above, in the method of manufacturing a semiconductor device, the channel stop groove portion 25d reaching the inside from an upper surface of the n-drift layer 3 in the termination region 102 is formed in the n-drift layer 3 provided in the active region 101 and the termination region 102. Then, an impurity of the first conductivity type is implanted into a surface layer of the n-drift layer 3 outside the channel stop groove portion 25d and a bottom portion of the channel stop groove portion 25d. Then, by activating the implanted impurity, the n type high concentration surface portion 25a in a surface layer of the n-drift layer 3 outside the channel stop groove portion 25d and the n type high concentration bottom portion 25b in a bottom portion of the channel stop groove portion 25d are formed.

According to such a configuration, it is possible to suppress extension of the depletion layer from the n channel stop portion 25 to an end portion of a chip, so that withstand voltage of the semiconductor device is stabilized and reliability is improved. Further, withstand voltage of the semiconductor device can be stabilized without increasing the number of manufacturing steps.

Further, even in a case where another configuration exemplified in the present description is appropriately added to the above configuration, that is, even in a case where another configuration in the present description not mentioned as the above configuration is appropriately added, a similar effect can be generated.

Further, according to the preferred embodiment described above, in the method of manufacturing a semiconductor device, the mark groove portion 26, which reaches the inside from an upper surface of the n-drift layer 3 of the dicing line region 104 surrounding the termination region 102 in plan view and is a mark used in a manufacturing step, is formed simultaneously with the channel stop groove portion 25d. According to such a configuration, the channel stop groove portion 25d and the mark groove portion 26 can be formed without adding a step.

### Regarding Variation of Plurality of Preferred Embodiments Described Above

In a plurality of the preferred embodiments described above, material property, a material, a dimension, a shape, a relative arrangement relationship, an implementation condition, and the like of each constituent element may also be described, but these are one example in all aspects and are not restrictive.

Accordingly, numerous variations and equivalents, examples of which are not shown, are assumed within a scope of a technique disclosed in the description of the present application. For example, a case where at least one constituent element is modified, added, or omitted, and a case where at least one constituent element in at least one preferred embodiment is extracted and combined with a constituent element in another preferred embodiment are included.

Further, in at least one preferred embodiment described above, in a case where a material name or the like is described without being particularly designated, unless there is a contradiction, the material includes another additive, for example, an alloy or the like. Hereinafter, various aspects of the present disclosure will be collectively described as an appendix.

### (Appendix 1)

A semiconductor device comprising an active region in which an element structure is formed, and a termination region surrounding the active region in plan view, the semiconductor device comprising:
a semiconductor layer of a first conductivity type provided in the active region and the termination region; and
a channel stop portion provided inside an outer end portion of the termination region, wherein
the channel stop portion includes:
a first channel stop groove portion formed to reach an inside from an upper surface of the semiconductor layer;
a first impurity portion of the first conductivity type formed on a surface layer of the semiconductor layer outside the first channel stop groove portion; and
a second impurity portion of the first conductivity type formed in a bottom portion of the first channel stop groove portion, and
impurity concentration of the first impurity portion and impurity concentration of the second impurity portion are higher than impurity concentration of the semiconductor layer.

### (Appendix 2)

The semiconductor device according to Appendix 1, wherein
the channel stop portion further includes a third impurity portion of the first conductivity type formed on a side surface of the first channel stop groove portion.

### (Appendix 3)

The semiconductor device according to Appendix 2, wherein
the third impurity portion is connected to the first impurity portion and the second impurity portion.

### (Appendix 4)

The semiconductor device according to Appendix 2 or 3, wherein
impurity concentration of the first impurity portion and impurity concentration of the second impurity portion are higher than impurity concentration of the third impurity portion.

### (Appendix 5)

The semiconductor device according to any one of Appendices 1 to 4, wherein
impurity concentration of the first impurity portion and impurity concentration of the second impurity portion are 1×10¹⁸/cm³ or more and 1×10²¹/cm³ or less.

### (Appendix 6)

The semiconductor device according to any one of Appendices 1 to 5 further comprising a dicing line region surrounding the termination region in plan view, wherein
the semiconductor layer is provided in the dicing line region, the semiconductor device further comprising an outer groove portion formed to reach the inside from an upper surface of the semiconductor layer in the dicing line region, wherein
depth of the outer groove portion is equal to depth of the first channel stop groove portion.

### (Appendix 7)

The semiconductor device according to any one of Appendices 1 to 6, wherein
a metal electrode is not provided in an upper portion of the channel stop portion.

### (Appendix 8)

The semiconductor device according to any one of Appendices 1 to 7, wherein
an upper portion of the channel stop portion is covered with an insulating film without a conductive material interposed between the upper portion of the channel stop portion and the insulating film.

### (Appendix 9)

The semiconductor device according to Appendix 8, wherein
thickness of the insulating film in an upper portion of the first channel stop groove portion is larger than thickness of the insulating film outside the first channel stop groove portion.

### (Appendix 10)

The semiconductor device according to any one of Appendices 1 to 9, wherein
the channel stop portion further includes:
a second channel stop groove portion formed apart from the first channel stop groove portion at a position farther from the active region than the first channel stop groove portion; and
a fourth impurity portion of the first conductivity type formed in a bottom portion of the second channel stop groove portion, and
impurity concentration of the fourth impurity portion is higher than impurity concentration of the semiconductor layer.

### (Appendix 11)

The semiconductor device according to any one of Appendices 1 to 10, wherein
the channel stop portion further includes:
a fifth impurity portion of the first conductivity type formed on a surface layer of the semiconductor layer at a position farther from the active region than the first impurity portion, and
impurity concentration of the fifth impurity portion is higher than impurity concentration of the semiconductor layer.

### (Appendix 12)

The semiconductor device according to any one of Appendices 1 to 11, further comprising a trench type MOS field effect transistor provided in the active region, wherein
depth of a trench in the trench type MOS field effect transistor is equal to depth of the first channel stop groove portion.

### (Appendix 13)

The semiconductor device according to any one of Appendices 1 to 12, wherein
the semiconductor layer is made from silicon carbide.

### (Appendix 14)

A method of manufacturing a semiconductor device including an active region in which an element structure is formed and a termination region surrounding the active region in plan view, the method comprising:
forming a first channel stop groove portion of a first conductivity type provided to reach an inside from an upper surface of a semiconductor layer in the termination region, the semiconductor layer being provided in the active region and the termination region;
implanting an impurity of the first conductivity type into a surface layer of the semiconductor layer outside the first channel stop groove portion and a bottom portion of the first channel stop groove portion; and
activating the implanted impurity to form a first impurity portion of the first conductivity type in a surface layer of the semiconductor layer outside the first channel stop groove portion and a second impurity portion of the first conductivity type in a bottom portion of the first channel stop groove portion.

### (Appendix 15)

The method of manufacturing a semiconductor device according to Appendix 14, further comprising forming an outer groove portion, which reaches the inside from an upper surface of the semiconductor layer in a dicing line region surrounding the termination region in plan view and is a mark used in a manufacturing step, simultaneously with the first channel stop groove portion.

While the disclosure has been shown and described in detail, the foregoing description is in all aspects illustrative and not restrictive. It is therefore understood that numerous modifications and variations can be devised.

What is claimed is:

1. A semiconductor device comprising an active region in which an element structure is formed, and a termination region surrounding the active region in plan view, the semiconductor device comprising:
a semiconductor layer of a first conductivity type provided in the active region and the termination region; and
a channel stop portion provided inside an outer end portion of the termination region, wherein
the channel stop portion includes:
a first channel stop groove portion formed to reach an inside from an upper surface of the semiconductor layer;
a first impurity portion of the first conductivity type formed on a surface layer of the semiconductor layer outside the first channel stop groove portion; and
a second impurity portion of the first conductivity type formed in a bottom portion of the first channel stop groove portion, and
impurity concentration of the first impurity portion and impurity concentration of the second impurity portion are higher than impurity concentration of the semiconductor layer.

2. The semiconductor device according to claim 1, wherein
the channel stop portion further includes a third impurity portion of the first conductivity type formed on a side surface of the first channel stop groove portion.

3. The semiconductor device according to claim 2, wherein
the third impurity portion is connected to the first impurity portion and the second impurity portion.

4. The semiconductor device according to claim 2, wherein
impurity concentration of the first impurity portion and impurity concentration of the second impurity portion are higher than impurity concentration of the third impurity portion.

5. The semiconductor device according to claim 1, wherein
impurity concentration of the first impurity portion and impurity concentration of the second impurity portion are 1×10¹⁸/cm³ or more and 1×10²¹/cm³ or less.

6. The semiconductor device according to claim 1, further comprising a dicing line region surrounding the termination region in plan view, wherein
the semiconductor layer is provided in the dicing line region, the semiconductor device further comprising an outer groove portion formed to reach the inside from an upper surface of the semiconductor layer in the dicing line region, wherein
depth of the outer groove portion is equal to depth of the first channel stop groove portion.

7. The semiconductor device according to claim 1, wherein
a metal electrode is not provided in an upper portion of the channel stop portion.

8. The semiconductor device according to claim 1, wherein
an upper portion of the channel stop portion is covered with an insulating film without a conductive material interposed between the upper portion of the channel stop portion and the insulating film.

9. The semiconductor device according to claim 8, wherein
thickness of the insulating film in an upper portion of the first channel stop groove portion is larger than thickness of the insulating film outside the first channel stop groove portion.

10. The semiconductor device according to claim 1, wherein
the channel stop portion further includes:
a second channel stop groove portion formed apart from the first channel stop groove portion at a position farther from the active region than the first channel stop groove portion; and
a fourth impurity portion of the first conductivity type formed in a bottom portion of the second channel stop groove portion, and
impurity concentration of the fourth impurity portion is higher than impurity concentration of the semiconductor layer.

11. The semiconductor device according to claim 1, wherein
the channel stop portion further includes:
a fifth impurity portion of the first conductivity type formed on a surface layer of the semiconductor layer at a position farther from the active region than the first impurity portion, and
impurity concentration of the fifth impurity portion is higher than impurity concentration of the semiconductor layer.

12. The semiconductor device according to claim 1, further comprising a trench type MOS field effect transistor provided in the active region, wherein
depth of a trench in the trench type MOS field effect transistor is equal to depth of the first channel stop groove portion.

13. The semiconductor device according to claim 1, wherein
the semiconductor layer is made from silicon carbide.

14. A method of manufacturing a semiconductor device including an active region in which an element structure is formed and a termination region surrounding the active region in plan view, the method comprising:
forming a first channel stop groove portion of a first conductivity type provided to reach an inside from an upper surface of a semiconductor layer in the termination region, the semiconductor layer being provided in the active region and the termination region;
implanting an impurity of the first conductivity type into a surface layer of the semiconductor layer outside the first channel stop groove portion and a bottom portion of the first channel stop groove portion; and
activating the implanted impurity to form a first impurity portion of the first conductivity type in a surface layer of the semiconductor layer outside the first channel stop groove portion and a second impurity portion of the first conductivity type in a bottom portion of the first channel stop groove portion.

15. The method of manufacturing a semiconductor device according to claim 14, further comprising forming an outer groove portion, which reaches the inside from an upper surface of the semiconductor layer in a dicing line region surrounding the termination region in plan view and is a mark used in a manufacturing step, simultaneously with the first channel stop groove portion.
